(19) United States
(12) Patent Application Publication
(10) Pub. No.: US 2024/0222162 A1
(43) Pub. Date: Jul. 4, 2024

(54) WAFER ANNEALING APPARATUS AND METHOD

(71) Applicant: Magnachip Semiconductor, Ltd., Cheongju-si (KR)

(72) Inventors: Jungyeon LEE, Seoul (KR); Seongchan JEON, Gumi-si (KR); Kihwan KIM, Seoul (KR); Kitae KANG, Gumi-si (KR); Jiyong LIM, Seoul (KR); Hohyun KIM, Seoul (KR); Chanho PARK, Seoul (KR)

(73) Assignee: Magnachip Semiconductor, Ltd., Cheongju-si (KR)

(21) Appl. No.: 18/457,240

(22) Filed: Aug. 28, 2023

(30) Foreign Application Priority Data
Dec. 29, 2022 (KR) 10-2022-0189762

(51) Int. Cl. H01L 21/67; H01L 21/324; H01L 21/687

(52) U.S. Cl. CPC H01L 21/67115; H01L 21/324; H01L 21/67248; H01L 21/68764

(57) ABSTRACT

A wafer annealing apparatus includes a gas supply unit located on one side of the wafer annealing apparatus and configured to supply high-temperature gases to transfer heat to wafers loaded inside the wafer annealing apparatus, a rotation driving unit comprising a rotation controller and configured to rotate a wafer support unit loaded with wafers, and a gas release unit located on the other side of the wafer annealing apparatus and configured to release the high-temperature gases fed to the wafer annealing apparatus. The rotation controller includes at least one processor configured to transmit a control signal to the rotation driving unit and control a rotation cycle and a rotation angle of the rotation driving unit.

### CROSS REFERENCE TO RELATED APPLICATION

The present application claims the benefit under 35 USC § 119(a) of Korean Patent Application No. 10-2022-0189762, filed Dec. 29, 2022, in the Korean Intellectual Property Office, the entire disclosure of which is incorporated herein by reference for all purposes.

### BACKGROUND

### 1. Field

The following description relates to a wafer annealing apparatus and method for uniformly transferring heat to wafers in a semiconductor annealing process.

### 2. Description of the Related Art

With the high integration of semiconductor devices, the line width of circuits becomes thinner, and the surface quality and near-surface internal characteristics of silicon wafers, the material of semiconductor devices, become more important.

The silicon wafer may be processed such that its surface and internal defects to a certain depth from the surface are to be controlled through high-temperature heat treatment. This heat treatment process is called an annealing process, and the annealing process may change the characteristics and quality of the wafer by applying a certain temperature to the wafer inside a processing device.

However, in a conventional wafer annealing apparatus or method, high-temperature gas supplied in an annealing process flows in a specific direction to transfer heat to the wafer, and imbalance in heat transfer may occur between a partial region of the wafer located in the specific direction in which the gas is supplied and a region opposite thereto. This can result in wafers that do not have the desired wafer characteristics and quality.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a wafer annealing apparatus includes a gas supply unit located on one side of the wafer annealing apparatus and configured to supply high-temperature gases to transfer heat to wafers loaded inside the wafer annealing apparatus, a rotation driving unit comprising a rotation controller and configured to rotate a wafer support unit including the wafers, and a gas release unit located on the other side of the wafer annealing apparatus and configured to release the high-temperature gases fed to the wafer annealing apparatus. The rotation controller includes at least one processor configured to transmit a control signal to the rotation driving unit and control a rotation cycle and a rotation angle of the rotation driving unit.

The wafer annealing apparatus may further include a fixing unit configured to fix the rotation driving unit and the wafer support unit, such that the wafer support unit is rotated through the fixing unit.

The fixing unit may be configured to fix the wafer support unit by adsorbing the wafer support unit against the rotation driving unit.

The fixing unit may be configured to fix the wafer support unit and the rotation driving unit using vacuum adsorption or magnetic adsorption.

The rotation controller is configured to control the rotation driving unit such that the wafer support unit rotates 180 degrees after the high-temperature gases are supplied to the wafers for a preset period of time to transfer heat to the wafers.

The preset period of time may be determined by a temperature of the high-temperature gases for transferring heat to the wafers.

The wafer annealing apparatus may further include a temperature measurement unit including a temperature sensor configured to measure a temperature of the high-temperature gases and transmit information on the measured temperature to the rotation controller.

The high-temperature gases that have transferred the heat to the wafers in the wafer support unit may be released through the gas release unit.

The wafer annealing apparatus may further include a pressure controller including a pressure sensor and configured to control an internal pressure by controlling the high-temperature gases released from the gas release unit.

The pressure control unit may be located to face the rotation driving unit.

In another general aspect, a wafer annealing method includes loading a wafer support unit including wafers onto a rotation driving unit of a wafer annealing apparatus, performing a first annealing step of transferring heat to the wafers by supplying high-temperature gases to one side of the wafers for a first preset period of time, rotating the wafer support unit, and performing a second annealing step of transferring heat to the wafers by supplying the high-temperature gases to the other side of the wafers for a second preset period of time.

The first annealing step may include locating a flat zone of each wafer on one side of each wafer to which the high-temperature gases are supplied.

Each of the first annealing step and the second annealing step may include a main annealing step and an additional annealing step.

The main annealing step may be performed at a temperature range of 330° ° C. to 360° ° C., and the additional annealing step may be performed at a temperature range of 390° C. to 410° C.

The first annealing step and the second annealing step are performed while an internal pressure of the wafer annealing apparatus is controlled.

The rotating of the wafer support unit may include rotating the wafer support unit so that a flat zone of each wafer is located on the other side of each wafer to which the high-temperature gases are supplied.

The first preset period of time may be set based on a temperature of the high-temperature gases, and the second preset period of time may be set to be equal to the first preset period of time.

According to one or more embodiments of the present disclosure, it is possible to uniformly transfer heat to wafers during a semiconductor annealing process. Accordingly, most regions of the wafers may have target threshold voltage values.

The effects that may be obtained in the present disclosure are not limited to the effects mentioned above, and other features and aspects will be apparent from the following detailed description, the drawings and the claims.

### BRIEF DESCRIPTION OF THE DRAWINGS

FIG. 1 illustrates a configuration of a wafer annealing apparatus according to one or more embodiments of the present disclosure.

FIG. 2 illustrates rotation of a rotation driving unit according to one or more embodiments of the present disclosure.

FIG. 3 illustrates a wafer support unit including a plurality of wafers according to one or more embodiments of the present disclosure.

FIG. 4 illustrates a threshold voltage distribution in a wafer before/after wafer rotation according to one or more embodiments of the present disclosure.

FIG. 5 illustrates a distribution of threshold voltages below an average voltage in a wafer before/after wafer rotation according to one or more embodiments of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items. Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof. Due to manufacturing techniques and/or tolerances, variations of the shapes shown in the drawings may occur. Thus, the examples described herein are not limited to the specific shapes shown in the drawings, but include changes in shape that occur during manufacturing. The features of the examples described herein may be combined in various ways as will be apparent after an understanding of the disclosure of this application. Further, although the examples described herein have a variety of configurations, other configurations are possible as will be apparent after an understanding of the disclosure of this application.

A term “unit” or “module” used in the embodiments may mean software components or hardware components such as a field programmable gate array (FPGA), an application specific integrated circuit (ASIC). The “unit” or “module” performs certain functions. However, the “unit” or “module” is not meant to be limited to software or hardware. The “unit” or “module” may be configured to be placed in an addressable storage medium or to restore one or more processors. Thus, for one example, the “unit” or “module” may include components such as software components, object-oriented software components, class components, and task components, and may include processes, functions, attributes, procedures, subroutines, segments of a program code, drivers, firmware, microcode, circuits, data, databases, data structures, tables, arrays, and variables. Components and functions provided in the “unit” or “module” may be combined with a smaller number of components and “units” or “modules” or may be further divided into additional components and “units” or “modules”.

Methods or algorithm steps described relative to some embodiments of the present disclosure may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the record medium may be resident within an application specific integrated circuit (ASIC). The ASIC may reside in a user terminal.

Hereinafter, embodiments of the present disclosure will be described in detail with reference to the accompanying drawings so that the present disclosure may be readily implemented by those skilled in the art. However, it is to be noted that the present disclosure is not limited to the embodiments but can be embodied in various other ways.

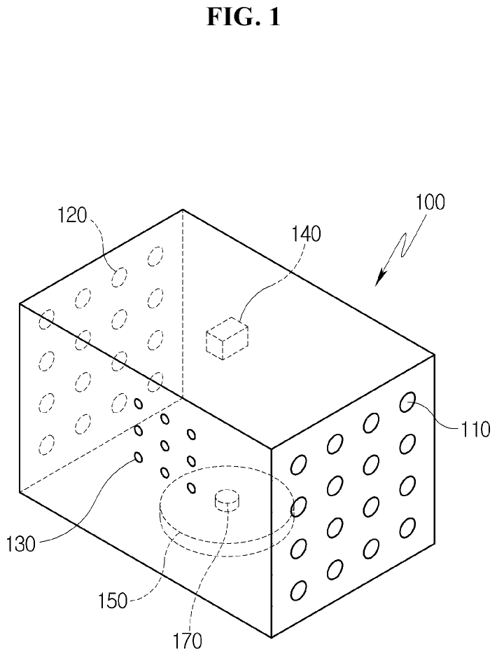

FIG. 1 illustrates a configuration of a wafer annealing apparatus 100 according to one or more embodiments of the present disclosure.

Referring to FIG. 1, a wafer annealing apparatus 100 according to one or more embodiments of the present disclosure may include a gas supply unit 110, a gas release unit 120, a temperature measurement unit 130, a pressure controller 140, and a rotation driving unit 150 comprising a rotation controller including at least one processor (not shown). Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

The gas supply unit 110 may supply high-temperature gas for transferring heat to a wafer. The gas supply unit 110 may be located on one side of the wafer annealing apparatus 100 to supply gas to a wafer. The gas supply unit 110 may supply gas to the wafer in a certain direction. The gas supplied from the gas supply unit 110 may be N2 or H2 or a mixed gas thereof. Herein, N2 or H2 may be a gas capable of transferring heat to a wafer without reacting with the wafer during an annealing process, but the gas supplied by the gas supply unit 110 is not limited to N2 or H2.

The gas release unit 120 may release gas supplied into the wafer annealing apparatus 100. The gas release unit 120 may be located on the other side of the wafer annealing apparatus 100 to release gas that has transferred heat to the wafer. The gas supply unit 110 is located on one side in the wafer annealing apparatus 100 and the gas release unit 120 is located on the other side opposite to the one side, so that the gas supplied from the gas supply unit 110 transfers heat to the wafer in such a way the gas is supplied to the wafer in the direction of the gas release unit 120, and the gas that has transferred heat to the wafer may be released through the gas release unit 120.

The temperature measurement unit 130 including a temperature sensor may measure the internal temperature of the wafer annealing apparatus 100. The internal temperature of the wafer annealing apparatus 100 may increase due to the high-temperature gas supplied from the gas supply unit 110. The gas supply unit 110 may supply high-temperature gas so as to reach a target temperature required for the annealing process, and the temperature measurement unit 130 may measure the internal temperature to identify whether the internal temperature of the wafer annealing apparatus 100 reaches the target temperature. The temperature measurement unit 130 may transmit information on the measured temperature to the rotation controller, and set a rotation period of the rotation driving unit 150 based on the information on the temperature.

The pressure controller 140 including a pressure sensor may be located to face the rotation driving unit 150 at the upper end of the wafer annealing apparatus 100 to control the internal pressure of the wafer annealing apparatus 100. When the internal pressure of the wafer annealing apparatus 100 increases or decreases based on the gas supplied from the gas supply unit 110, the pressure controller 140 may control the amount of internal gas such that the internal pressure of the wafer annealing apparatus 100 has a predetermined value. Since the internal pressure may affect the temperature of the annealing process and the heat transfer reaction of the wafer, the pressure controller 140 may control the release of gas such that the internal pressure of the wafer annealing apparatus 100 has a preset pressure.

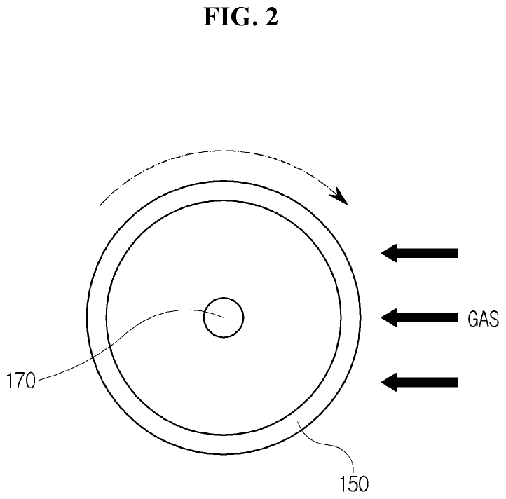

FIG. 2 illustrates rotation of the rotation driving unit 150 according to one or more embodiments of the present disclosure.

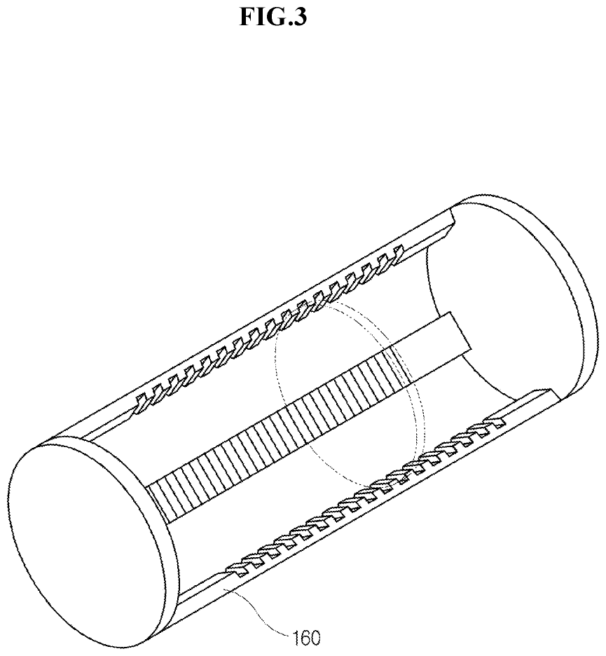

FIG. 3 illustrates a wafer support unit including a plurality of wafers according to one or more embodiments of the present disclosure.

Referring to FIGS. 2 and 3, a wafer support unit 160 including a wafer may be placed on the rotation driving unit 150 during a wafer annealing process. The wafer support unit 160 may support a plurality of wafers. The wafer support unit 160 may be implemented with a quartz boat, but is not limited thereto. The rotation driving unit 150 may support and fix the wafer support unit 160 such that the wafer included in the wafer support unit 160 is able to receive heat from high-temperature gas supplied from the gas supply unit 110 during the annealing process. The rotation driving unit 150 may be disposed under the wafer support unit 160, and the wafer support unit 160 may be rotated by the rotation driving unit 150. The rotation driving unit 150 has a turntable-like structure to be rotatable, but the structure of the rotation driving unit 150 is not limited thereto. The rotation driving unit 150 may rotate during the annealing process such that a flat zone, a portion of a wafer supported by the wafer support unit 160 facing gas supplied from the gas supply unit 110, is changed. Accordingly, heat may be uniformly transferred to the wafer through the high-temperature gas supplied during the annealing process.

The wafer annealing apparatus 100, in an example, may further include a fixing unit 170 for fixing the rotation driving unit 150 and the wafer support unit 160. The fixing unit 170 may fix the wafer support unit 160 and the rotation driving unit 150 in a vacuum adsorption or magnetic adsorption method, but the fixing method is not limited thereto. Therefore, when the rotation driving unit 150 rotates, the wafer support unit 160 may be rotated through the fixing unit 170. The rotation driving unit 150 may rotate according to a control signal from the rotation controller. A rotation cycle and a rotation angle of the rotation driving unit 150 may vary according to a control signal from the rotation controller. The rotation driving unit 150 may rotate the wafer support unit 160 in the annealing process such that a portion of the wafer included in the wafer support unit 160 facing the gas supplied from the gas supply unit 110 is changeable.

The rotation controller including at least one processor (not shown) may control the rotation cycle and rotation angle of the rotation driving unit 150. The rotation controller may control the rotation cycle of the rotation driving unit 150 based on the internal temperature of the wafer annealing apparatus 100 received from the temperature measurement unit 130. When the internal temperature of the wafer annealing apparatus 100 is high, the rotation controller may control the rotation cycle of the rotation driving unit 150 to be short. Conversely, when the internal temperature of the wafer annealing apparatus 100 is low, the rotation controller may control the rotation cycle of the rotation driving unit 150 to be long.

The rotation controller may control the rotation driving unit 150 to rotate the wafer support unit 160 by 180 degrees after heat is transferred to the wafer by supplying gas to the wafer for a first preset period of time T1. In this case, the first preset period of time T1 may be determined by the temperature of gas for transferring heat to the wafer. Also, the first preset period of time T1 may be set in inverse proportion to the internal temperature of the wafer annealing apparatus 100. As the internal temperature of the wafer annealing apparatus 100 is lower, T1 may increase. Conversely, as the internal temperature of the wafer annealing apparatus 100 becomes higher, T1 may decrease. In addition, the first preset period of time T1 may be set differently depending on a type of gas supplied, an intensity of pressure, a wafer configuration, an annealing method, and the like, but is not limited thereto.

The rotation controller may control the rotation driving unit 150 to rotate 180 degrees based on the internal temperature of the wafer annealing apparatus 100 received from the temperature measurement unit 130 after the first preset period of time T1 when the gas has transferred heat to the wafer. The wafer included in the wafer support unit 160 may be rotated 180 degrees by the rotation of the rotation driving unit 150. The gas supplied to the inside of the wafer annealing apparatus 100 may flow in a certain direction from the gas supply unit 110 toward the gas release unit 120, and when the wafer is rotated, a portion of the wafer facing the gas (the flat zone) may be changed. Heat may be uniformly transferred to the wafer as a portion of the wafer facing the gas is changed.

Hereinafter, a wafer annealing method according to one or more embodiments of the present disclosure will be described.

A wafer annealing method, in an example, may include a first annealing step of transferring heat to a wafer and a second annealing step of transferring heat to the wafer.

In the first annealing step, heat may be transferred to the wafer by supplying high-temperature gas to one side of the wafer for a first preset period of time T1.

Specifically, the wafer support unit 160 including the wafer may be placed inside the wafer annealing apparatus 100. The gas supply unit 110 positioned on one side of the wafer annealing apparatus 100 may supply the high-temperature gas into the wafer annealing apparatus 100. The supplied gas may transfer heat to the wafer included in the wafer support unit 160. The gas that has transferred heat may be released through the gas release unit 120 positioned on the other side of the wafer annealing apparatus 100. The internal temperature of the wafer annealing apparatus 100 may increase due to the gas supplied from the gas supply unit 110.

The temperature measurement unit 130 including a temperature sensor may measure the internal temperature of the wafer annealing apparatus 100. Information on the internal temperature measured by the temperature measurement unit 130 may be transmitted to the rotation controller. The rotation controller may transmit a control signal to the rotation driving unit 150 such that the rotation driving unit 150 rotates 180 degrees after the first preset period of time T1 during which a preset internal temperature has been reached has elapsed based on the received information on the internal temperature. Here, the first preset period of time T1 may be set in inverse proportion to the internal temperature. For example, T1 may be set to be shorter as the internal temperature is higher, or T1 may be set to be longer as the internal temperature is lower.

In addition, the first preset period of time T1 may be set differently depending on a type of gas supplied, an intensity of pressure, a wafer configuration, an annealing method, and the like, but is not limited thereto. A first annealing step may be performed on the wafer according to T1 which is set based on the internal temperature. After the first preset period of time T1 has elapsed, the rotation driving unit 150 may rotate the wafer support unit 160 including the wafer by 180 degrees according to a control signal from the rotation controller. That is, the wafer may be rotated 180 degrees after the first annealing step.

After rotating the wafer by 180 degrees, in a second annealing step, high-temperature gas may be supplied to the other side of the wafer for the second preset period of time T2 to transfer heat to the wafer. As described above, T1 may be determined by a temperature of gas for transferring heat to the wafer, and T2 may be the same period of time as T1. It is noted that T2 may be set to a period of time different from T1 due to other factors, such as a change in internal pressure during the annealing process, but is not limited thereto. During T2, the same gas as in the first annealing step described above may transfer heat to the wafer. The wafer may be rotated 180 degrees to face the gas at a portion opposite to a portion which has faced the gas in the first annealing step and receive heat.

That is, in the first annealing step, the wafer may receive heat in such a way to face high-temperature gas in one area (e.g., Flat Zone) of the wafer, and may be then rotated 180 degrees. In the second annealing step, the wafer may receive heat in such a way to face high-temperature gas in an opposite area (opposite area to the Flat Zone) of the wafer. Accordingly, heat may be uniformly transferred to the wafer during the wafer annealing process.

Hereinafter, the effect of the wafer annealing method of the wafer annealing apparatus according to one or more embodiments of the present disclosure will be described.

Table 1 below shows examples of wafer annealing methods.

TABLE 1

| | No wafer rotation | Wafer rotation |
|---|---|---|
| Conditions | Supply gas at | 1. First annealing step (T1) |
| | 350° C. for more | Main annealing step(supply gas at |
| | than 30 minutes | temperature in range of from 330° C. |
| | and then supply | to less than 360° C. for more than |
| | gas at 400° C. | 15 minutes). |
| | for less | Additional annealing step(supply gas at |
| | than 10 minutes | temperature in range of from 390° C. |
| | | to less than 410° C. for less than |
| | | 5 minutes). |
| | | 2. Rotate wafer 180 degrees. |
| | | 3. Second annealing step (T2) |
| | | Main annealing step(supply gas at |
| | | temperature in range of from 330° C. |
| | | to less than 360° C. for more than |
| | | 15 minutes). |
| | | Additional annealing step(supply gas at |
| | | temperature in range of from 390° C. |
| | | to less than 410° C. for less than |
| | | 5 minutes). (Unless there are |
| | | special reasons, T2 = T1) |

Before/after electron irradiation

| | Before | After | Before | After |
|---|---|---|---|---|
| | electron | electron | electron | electron |
| | irradiation | irradiation | irradiation | irradiation |
| Average | 0.879 | 0.991 | 0.878 | 0.981 |
| Standard | 0.007 | 0.012 | 0.006 | 0.009 |
| deviation | | | | |

Referring to Table 1, Table 1 shows the average value and the standard deviation of the threshold voltages of the wafer in a case where there is wafer rotation and a case where there is no wafer rotation in the annealing process before and after electron irradiation for a semiconductor wafer according to an embodiment of the present disclosure.

In a case where there is wafer rotation, after the first annealing step T1 is completed, the wafer is then rotated 180 degrees and the second annealing step T2 is then performed. Each of the first annealing step and the second annealing step may include a main annealing step and an additional annealing step. The main annealing step may be performed at a temperature range of 330° ° C. to 360° C., and the optimum temperature may be 350° C. The additional annealing step may be performed at a temperature range of 390° C. to 410° C., and the optimum temperature may be 400° C.

It can be seen that the standard deviation of the threshold voltage of the wafer before/after electron irradiation has increased from 0.007 to 0.012 by about 71% in the case of no wafer rotation.

On the other hand, it can be seen that the standard deviation of the threshold voltage of the wafer before/after electron irradiation has increased from 0.006 to 0.009 by about 50% in the case of wafer rotation according to one or more embodiments of the present disclosure. That is, it can be seen that the heat by the high-temperature gas is uniformly transferred to the wafer because the increase amount of standard deviation before and after electron irradiation is reduced compared to the case where there is no wafer rotation.

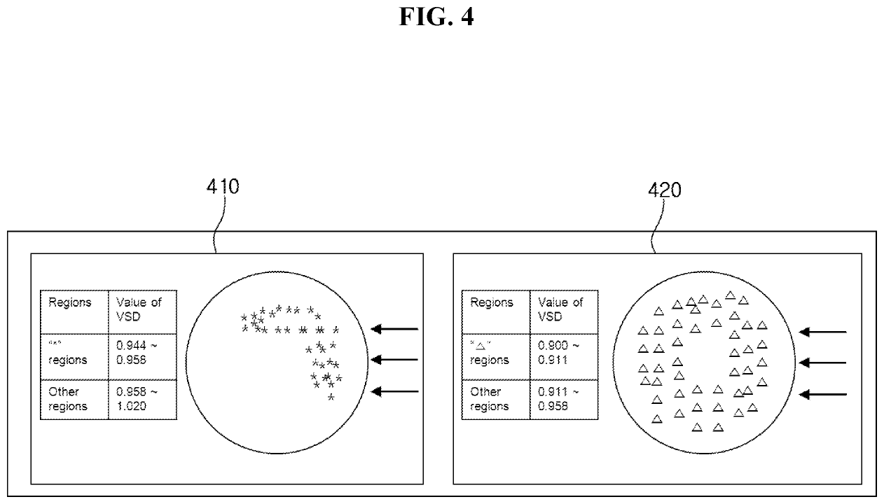

FIG. 4 illustrates a distribution of threshold voltage in a wafer before/after wafer rotation according to one or more embodiments of the present disclosure.

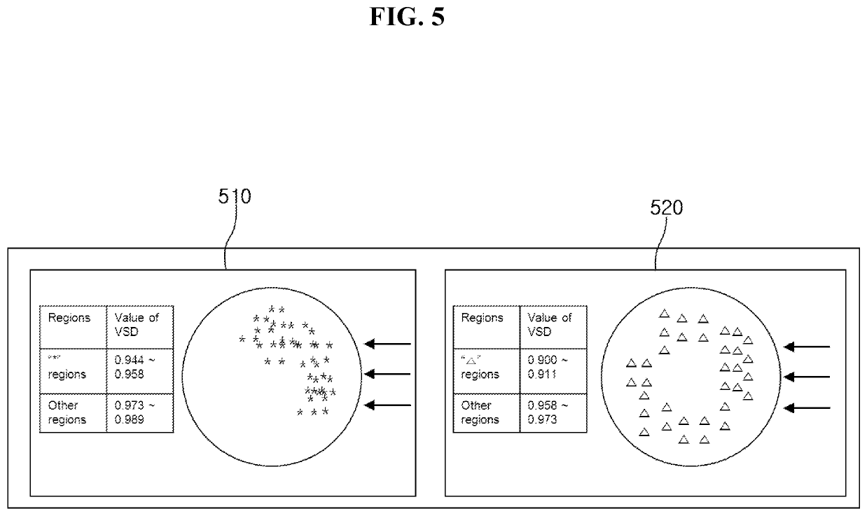

Referring to FIG. 4 and Table 1, under the condition of Table 1 described above, a distribution of threshold voltage in a wafer when there is no wafer rotation and a distribution of threshold voltage in a wafer when there is wafer rotation are shown. In FIGS. 4 and 5, when a region has a high VSD value, the region has a low threshold voltage value. Conversely, when a region has a low VSD value, the region has a high threshold voltage value.

When there is no wafer rotation (410), a threshold voltage in the right portion of the wafer facing the direction of gas supplied may have a value similar to a target threshold voltage, while a threshold voltage in the left portion of the wafer opposite to the direction of the gas supplied may have a lower threshold voltage value than the target threshold voltage. In addition, the standard deviation of all threshold voltages in the wafer may appear somewhat high due to a difference in threshold voltage between the left portion and the right portion of the wafer.

On the other hand, when the wafer is rotated (420), the threshold voltages in the right and left portions of the wafer may have values similar to the target threshold voltage. In addition, the standard deviation of all threshold voltages in the wafer may appear low compared to the case 410 in which there is no wafer rotation. That is, when the wafer is rotated by the wafer annealing method according to one or more embodiments of the present disclosure, heat may be uniformly transferred to the wafer during the annealing process.

FIG. 5 illustrates a distribution of threshold voltages equal to and less than an average in a wafer before/after wafer rotation according to one or more embodiments of the present disclosure.

Referring to FIG. 5 and Table 1, under the conditions of Table 1 described above, there are shown a distribution of threshold voltages equal to and less than the average with respect to the target threshold voltage in a wafer when there is no wafer rotation and a distribution of threshold voltages equal to and larger than the average with respect to the target threshold voltage in a wafer when there is wafer rotation.

When the wafer is not rotated (510), the right portion of the wafer facing the direction of the supplied gas has a higher heat quantity than the left portion which the gas does not face, so that the value of the threshold voltage in the left portion of the wafer may be lower than the average value of the threshold voltages of the entire wafer.

On the other hand, when the wafer is rotated (520), heat is uniformly transferred from the gas to the right and left portions of the wafer through rotation, so that the value of the threshold voltages in the right and left portions of the wafer are higher than the average value of the threshold voltages of the entire wafer. That is, when the wafer is rotated by the wafer annealing method according to one or more embodiments of the present disclosure, heat can be uniformly transferred to the wafer during the annealing process.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A wafer annealing apparatus, comprising:
a gas supply unit located on one side of the wafer annealing apparatus and configured to supply high-temperature gases to transfer heat to wafers loaded inside the wafer annealing apparatus;
a rotation driving unit comprising a rotation controller and configured to rotate a wafer support unit including the wafers; and
a gas release unit located on the other side of the wafer annealing apparatus and configured to release the high-temperature gases fed to the wafer annealing apparatus,
wherein the rotation controller comprises at least one processor configured to transmit a control signal to the rotation driving unit and control a rotation cycle and a rotation angle of the rotation driving unit.

2. The wafer annealing apparatus of claim 1, further comprising:
a fixing unit configured to fix the rotation driving unit and the wafer support unit, such that the wafer support unit is rotated through the fixing unit.

3. The wafer annealing apparatus of claim 2, wherein the fixing unit is configured to fix the wafer support unit by adsorbing the wafer support unit against the rotation driving unit.

4. The wafer annealing apparatus of claim 3, wherein the fixing unit is configured to fix the wafer support unit and the rotation driving unit using vacuum adsorption or magnetic adsorption.

5. The wafer annealing apparatus of claim 1, wherein the rotation controller is configured to control the rotation driving unit such that the wafer support unit rotates 180 degrees after the high-temperature gases are supplied to the wafers for a preset period of time to transfer heat to the wafers.

6. The wafer annealing apparatus of claim 5, wherein the preset period of time is determined by a temperature of the high-temperature gases for transferring heat to the wafers.

7. The wafer annealing apparatus of claim 1, further comprising:
a temperature measurement unit including a temperature sensor configured to measure a temperature of the high-temperature gases and transmit information on the measured temperature to the rotation controller.

8. The wafer annealing apparatus of claim 1, wherein the high-temperature gases that have transferred the heat to the wafers in the wafer support unit are released through the gas release unit.

9. The wafer annealing apparatus of claim 8, further comprising:
a pressure controller including a pressure sensor and configured to control an internal pressure by controlling the high-temperature gases released from the gas release unit.

10. The wafer annealing apparatus of claim 9, wherein the pressure controller is located to face the rotation driving unit.

11. A wafer annealing method comprising:
loading a wafer support unit including wafers onto a rotation driving unit of a wafer annealing apparatus;
performing a first annealing step of transferring heat to the wafers by supplying high-temperature gases to one side of the wafers for a first preset period of time;
rotating the wafer support unit; and
performing a second annealing step of transferring heat to the wafers by supplying the high-temperature gases to the other side of the wafers for a second preset period of time.

12. The wafer annealing method of claim 11, wherein the first annealing step comprises:
locating a flat zone of each wafer on one side of each wafer to which the high-temperature gases are supplied.

13. The wafer annealing method of claim 11, wherein each of the first annealing step and the second annealing step comprises a main annealing step and an additional annealing step.

14. The wafer annealing method of claim 13, wherein the main annealing step is performed at a temperature range of 330° ° C. to 360° C., and
wherein the additional annealing step is performed at a temperature range of 390° C. to 410° C.

15. The wafer annealing method of claim 11, wherein the first annealing step and the second annealing step are performed while an internal pressure of the wafer annealing apparatus is controlled.

16. The wafer annealing method of claim 11, wherein the rotating of the wafer support unit comprises:
rotating the wafer support unit so that a flat zone of each wafer is located on the other side of each wafer to which the high-temperature gases are supplied.

17. The wafer annealing method of claim 11, wherein the first preset period of time is set based on a temperature of the high-temperature gases, and
wherein the second preset period of time is set to be equal to the first preset period of time.
